(19) United States
(12) Patent Application Publication
(10) Pub. No.: US 2026/0143804 A1
(43) Pub. Date: May 21, 2026

(54) COMPLEMENTARY FIELD EFFECT TRANSISTOR (CFET) STRUCTURE

(71) Applicant: TAIWAN SEMICONDUCTOR MANUFACTURING COMPANY LTD., HSINCHU (TW)

(72) Inventors: YI-YI CHEN, KEELUNG CITY (TW); CHI-YU LU, NEW TAIPEI CITY (TW); CHIH-LIANG CHEN, HSINCHU CITY (TW); CHEN-LING WU, TAOYUAN CITY (TW); YA-CHI CHOU, HSINCHU CITY (TW)

(21) Appl. No.: 18/948,567

(22) Filed: Nov. 15, 2024

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 84/0188; H10D 84/038; H10D 88/01

(57) ABSTRACT

A semiconductor structure includes a first transistor, a second transistor, a gate structure, and a gate isolation. The first transistor is of a first conductivity type and comprises a first active region structure. The second transistor is of a second conductivity type different from the first conductivity type and comprises a second active region structure. The second transistor is disposed above the first transistor. The gate structure comprises a first gate connection contacting the first active region structure and a second gate connection contacting the second active region structure. The gate isolation is disposed between the first gate connection and the second gate connection.

### TECHNICAL FIELD

The present disclosure relates in general, to semiconductor structures. Specifically, the present disclosure relates to complementary field effect transistor (CFET) structures.

### BACKGROUND

A problem faced by existing process is that there are fewer routing tracks in CFET structure. To reduce cell area of the semiconductor structure and increase flexibility of layout, an improved CFET structure is called for.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 is a cross-section of a semiconductor structure in accordance with some embodiments of the present disclosure.

FIG. 2a is a schematic layout diagram of an upper portion of a semiconductor structure in accordance with some embodiments of the present disclosure.

FIG. 2b is a schematic layout diagram of a lower portion of a semiconductor structure in accordance with some embodiments of the present disclosure.

FIG. 3 is a top view of the upper portion of a semiconductor structure in accordance with some embodiments of the present disclosure.

FIG. 4 is a three-dimensional view of a semiconductor structure in accordance with some embodiments of the present disclosure.

FIG. 5 is a three-dimensional view of a semiconductor structure in accordance with some embodiments of the present disclosure.

FIG. 6 is a cross-section of a semiconductor structure in accordance with some embodiments of the present disclosure.

FIG. 7a is a schematic layout diagram of an upper portion of a semiconductor structure in accordance with some embodiments of the present disclosure.

FIG. 7b is a schematic layout diagram of a lower portion of a semiconductor structure in accordance with some embodiments of the present disclosure.

FIGS. 8a-8j are cross-sections of semiconductor structures in accordance with some embodiments of the present disclosure.

FIG. 9 is a block diagram of an integrated circuit (IC) manufacturing system, and an IC manufacturing flow associated therewith, in accordance with some embodiments.

FIG. 10 is a flowchart of an embodiment of a method 1000 of manufacturing a semiconductor structure in accordance with some embodiments of the present disclosure.

### DETAILED DESCRIPTION

The following disclosure provides multiple embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90° (degree) or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

A problem faced by existing process is that there are fewer routing tracks in CFET structure. An improved CFET structure reduces cell area of semiconductor structure and increases layout flexibility.

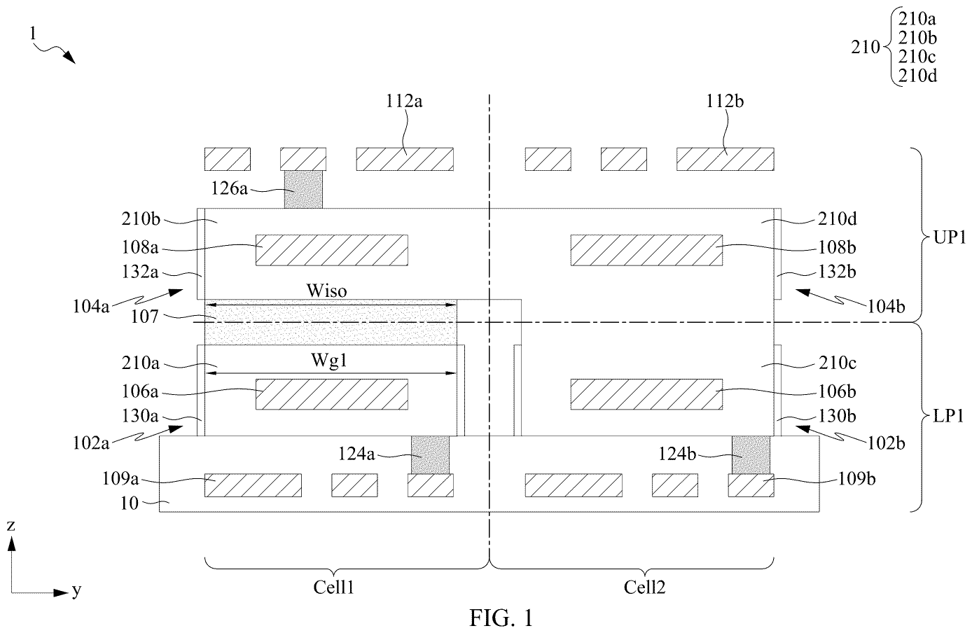

FIG. 1 is a cross-section of a semiconductor structure 1 in accordance with some embodiments of the present disclosure. The semiconductor structure 1 (also referred to herein as “two cells”) includes a semiconductor substrate 10 (e. g, a silicon substrate), a first transistor 102a, a second transistor 104a, a third transistor 102b, and a fourth transistor 104b. The second transistor 104a is disposed above the first transistor 102a. The fourth transistor 104b is disposed above the third transistor 102b. In the structure shown in FIG. 1, one cell includes the first transistor 102a and the second transistor 104a, and another includes the third transistor 102b and the fourth transistor 104b.

In some embodiments, the first transistor 102a is of a first conductivity type and comprises a first active region structure 106a. The second transistor 104a is of a second conductivity type different from the first conductivity type and comprises a second active region structure 108a. The second transistor is disposed above the first transistor 102a. In some embodiments, the third transistor 102b is of the first conductivity type and comprises a third active region structure 106b. The fourth transistor 104b is of the second conductivity type and comprises a fourth active region structure 108b. The fourth transistor 104b is disposed above the third transistor 102b.

In some embodiments, the semiconductor structure 1 includes a gate structure 210. The gate structure 210 includes a first gate connection 210a contacting the first active region structure 106a and a second gate connection 210b contacting the second active region structure 108a. The gate structure 210 further includes a third gate connection 210c contacting the third active region structure 106b and a fourth gate connection 210d contacting the fourth active region structure 108b. The third gate connection 210c and the fourth gate connection 210d are formed integrally. In some embodiments, the second gate connection 210b, the third gate connection 210c, and the fourth gate connection 210d are further formed integrally.

In some embodiments, a gate isolation 107 is disposed between the first gate connection 210a and the second gate connection 210b. The top end of the gate isolation 107 contacts the second gate connection 210b and the bottom end of the gate isolation 107 contacts the first gate connection 210a. The first gate connection 210a and the second gate connection 210b are electrically isolated by the gate isolation 107. A top end of the gate isolation 107 is coplanar with a bottom end of the second gate connection 210b. A lateral width Wg1 of the first gate connection 210a is substantially the same as a lateral width Wiso of the gate isolation 107. The one body formation of the second gate connection 210b, the third gate connection 210c, and the fourth gate connection 210d can increase the routing tracks in CFET structures and reduce the length of the cell pitches. The design of the structures improves flexibility of the routing of the CFET structures. In some embodiments, the design can reduce the coupling of the metal layer due to the clear metal routings of CFET structures. The design of the structures increases flexibility for the circuit design. The first transistor 102a and the second transistor 104a which comprise different gate connections are respectively controlled by different control signals due to the electrical isolation of the gate isolation 107. In some embodiments, any of the gate connections 210a-210d can be replaced with dielectric materials or electrical isolation materials.

Each of the first transistor 102a and the third transistor 102b is a P-MOSFET (P-channel metal-oxide semiconductor field-effect transistor, e.g. the first conductivity type) and each of the second transistor 104a and the fourth transistor 104b is a N-MOSFET (e.g. the second conductivity type). In some embodiments, each of the first transistor 102a and the third transistor 102b is a N-MOSFET and each of the second transistor 104a and the fourth transistor 104b is a P-MOSFET. In some embodiments, the first transistor 102a and the second transistor 104a are formed as a CFET. In some embodiments, the CFET has a first-type transistor stacked with a second-type transistor. Alternatively, the first-type transistor may have a channel (active) region in a first-type active-region semiconductor structure, and the second-type transistor may have a channel region in a second-type active-region semiconductor structure. In some embodiments, the transistor stack includes a front-side conductive layer above the CFET transistors and a back-side conductive layer below the CFET transistors. In some embodiments, CFET performance improves based upon the positioning of a power conductive line, signal conductive lines, and a shielding conductive line. In some embodiments, the power connections to the CFET are improved with reduced resistance between the CFET and the power conductive lines based on the increased size of the power conductive line. In some embodiments, signal shielding for the front-side signal conductive lines is improved by the front-side shielding conductive line and inter-CFET signal shielding is improved by the back-side shielding conductive lines.

In some embodiments, the second transistor 104a, the third transistor 102b, and the fourth transistor 104b are configured to receive a control signal through the second gate connection 210b, the third gate connection 210c, and the fourth gate connection 210d. In some embodiments, the first transistor 102a is configured to receive another control signal through the first gate connection 210a. In some embodiments, a plurality of first conductive lines 112a is disposed in a first metal layer above the second transistor 104a. One of the plurality of first conductive lines 112a is electrically connected to the second gate connection 210b through, for example, a conductive via 126a. In some embodiments, the first transistor 102a is constructed in such a way that a P-type transistor includes an input from a voltage source or VDD. The second transistor 104a includes an N-type transistor that includes an input from VSS or ground. In some embodiments, the outputs of the P-type and N-type transistors are complementary such that when the input is low, the output is high, and when the input is high, the output is low. Because of this behavior of input and output, in some embodiments, the CMOS circuit output is the inverse of the input.

In some embodiments, the semiconductor structure 1 includes a source/drain connection 130a, a source/drain connection 130b, a source/drain connection 132a, a source/drain connection 132b, and conductive vias 124a, 124b, and 126a. In some embodiments, the semiconductor structure 1 includes a plurality of first conductive lines 112a and 112b and a plurality of second conductive lines 109a and 109b.

In some embodiments, the first transistor 102a is electrically connected to one of the plurality of second conductive lines 109a through the conductive via 124a and the third transistor 102b is electrically connected to one of the plurality of second conductive lines 109b through the conductive via 124b. In some embodiments, the second transistor 104a and the fourth transistor 104b are electrically connected to one of the plurality of first conductive lines 112a through the conductive via 126a. In some embodiments, the conductive lines 112a, 112b, 109a, and 109b are one or more conductive materials, e.g., a metal such as copper, aluminum, tungsten, titanium, polysilicon, or another material capable of providing a low resistance signal path. In some embodiments, the conductive via 124a, 124b, and 126a are one or more conductive materials, e.g., a metal such as copper, aluminum, tungsten, titanium, polysilicon, or another material capable of providing a low resistance signal path.

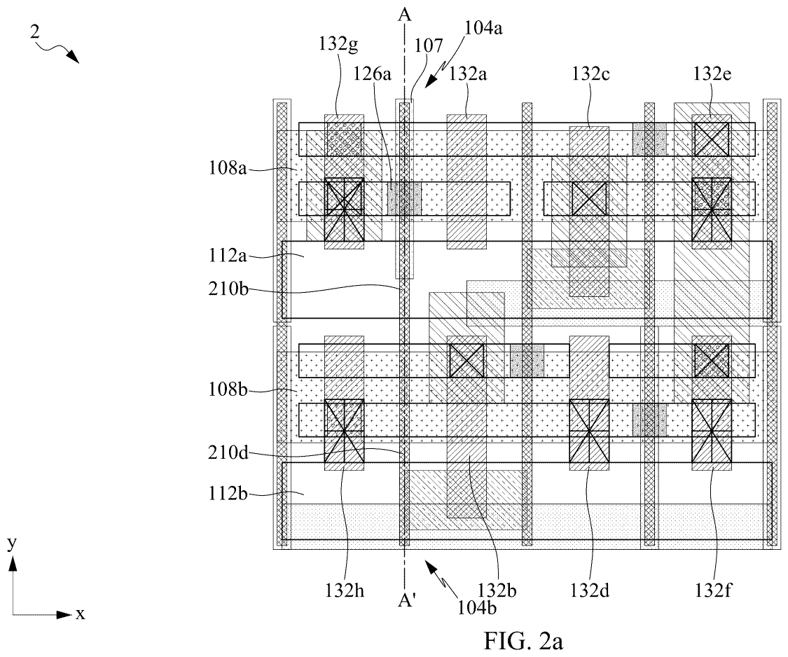

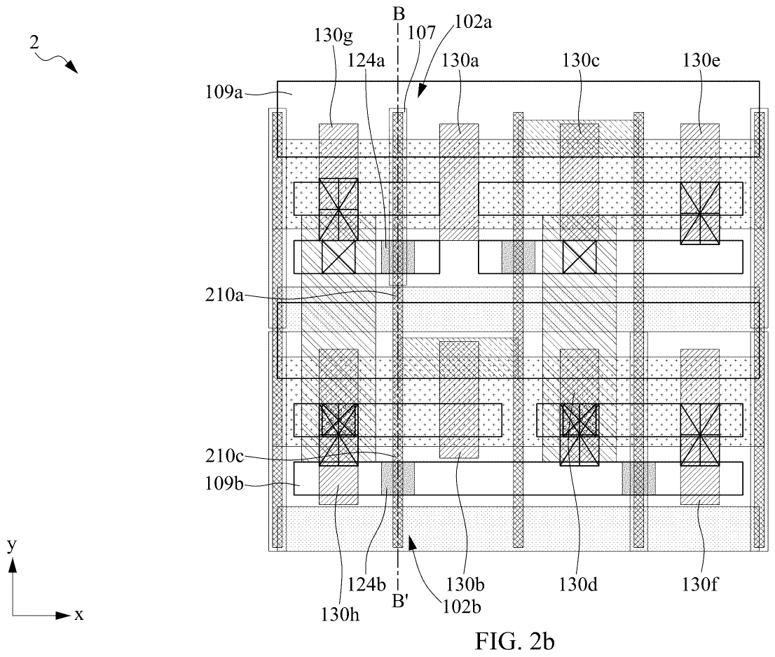

FIG. 2a is a schematic layout diagram of an upper portion of a semiconductor structure 2, in accordance with some embodiments of the present disclosure. The upper portion UP1 of the cross-section of the semiconductor structure 1 is obtained along line A-A′ of the upper portion of the semiconductor structure 2. The semiconductor structure 2 includes the second transistor 104a, the fourth transistor 104b, the second active region structure 108a, the fourth active region structure 108b, the second gate connection 210b, and the fourth gate connection 210d. In some embodiments, the upper portion of the semiconductor structure 2 includes a source/drain connection 132a and a source/drain connection 132b. In some embodiments, the upper portion of the semiconductor structure 2 includes the gate isolation 107, the conductive via 126a, and the plurality of the first conductive lines 112a. In some embodiments, the upper portion of the semiconductor structure 2 includes eight source/drain connections 132a-132h. In some embodiments, one of a plurality of first conductive lines 112a is electrically connected to the second gate connection 210b through a conductive via 126a. In some embodiments, a projection area of the conductive via 126a exceeds a projection area of the second gate connection 210b from the top view. In some embodiments, a width of the conductive via 126a is greater than a width of the second gate connection 210b from the top view. In some embodiments, a projection area of two ends of the source/drain connection 132a exceeds a projection area of two ends of the second active region structure 108a from the top view along the y direction. FIG. 2b is a schematic layout diagram of a lower portion of the semiconductor structure 2 in accordance with some embodiments of the present disclosure. The lower portion LP1 of the cross-section of the semiconductor structure 1 is obtained along line B-B′ of the lower portion of the semiconductor structure 2. The semiconductor structure 2 includes a first transistor 102a and a third transistor 102b. The lower portion of the semiconductor structure 2 includes the first transistor 102a, the third transistor 102b, the first active region structure 106a, the third active region structure 106b, the first gate connection 210a, and the second gate connection 210c. In some embodiments, the lower portion of the semiconductor structure 2 includes a source/drain connection 130a and a source/drain connection 130b. In some embodiments, the semiconductor structure 2 includes the gate isolation 107, a conductive via 124a, and the plurality of second conductive lines 109a. In some embodiments, the semiconductor structure 2 includes eight source/drain connections 130a-130h.

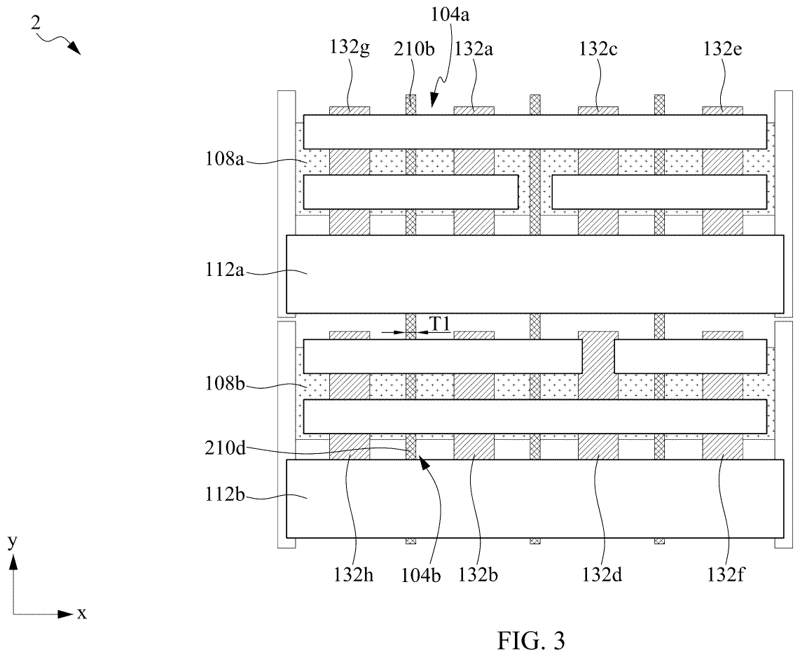

FIG. 3 is top view of the upper portion UP1 of the semiconductor structure 2 in accordance with some embodiments of the present disclosure. The upper portion UP1 of the semiconductor structure 2 includes the second transistor 104a, the fourth transistor 104b, the second active region structure 108a, the fourth active region structure 108b, the second gate connection 210b, and the fourth gate connection 210d. In some embodiments, the semiconductor structure 2 includes a source/drain connection 132a and a source/drain connection 132b. In some embodiments, the semiconductor structure 2 includes a plurality of first conductive lines 112a and a plurality of second conductive lines 112b. In some embodiments, the semiconductor structure 2 includes eight source/drain connections. In some embodiments, the second gate connection 210b of the second transistor 104a contacts the fourth gate connection 210d of the fourth transistor 104b from a top view. In some embodiments, the second gate connection 210b of the second transistor 104a and the fourth gate connection 210d of the fourth transistor 104b are formed integrally from the top view. A width T1 of the second gate connection 210b is the same as a width T1 of the fourth gate connection 210d from the top view. In some embodiments, a width T1 of the second gate connection 210b is the same as a width T1 of the gate isolation 107 from the top view.

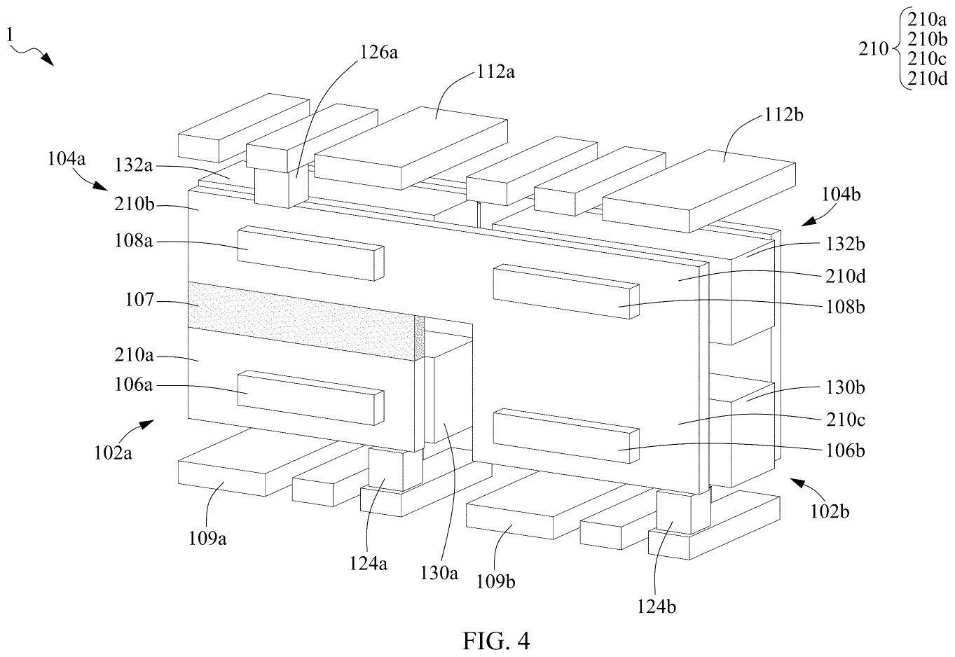

FIG. 4 is a three-dimensional view of a semiconductor structure 1 in accordance with some embodiments of the present disclosure. The semiconductor structure 1 includes a first transistor 102a, a second transistor 104a, a third transistor 102b, and a fourth transistor 104b. The second transistor 104a is disposed above the first transistor 102a. The fourth transistor 104b is disposed above the third transistor 102b. One cell includes the first transistor 102a and the second transistor 104a. Another includes the third transistor 102b and the fourth transistor 104b.

In some embodiments, the first transistor 102a is of a first conductivity type and comprises a first active region structure 106a. The second transistor 104a is of a second conductivity type different from the first conductivity type and comprises a second active region structure 108a. In some embodiments, the third transistor 102b is of the first conductivity type and comprises a third active region structure 106b. The fourth transistor 104b is of the second conductivity type and comprises a fourth active region structure 108b. The gate structure 210 includes a first gate connection 210a contacting the first active region structure 106a, a second gate connection 210b contacting the second active region structure 108a, a third gate connection 210c contacting the third active region structure 106b, and a fourth gate connection 210d contacting the fourth active region structure 108b. The third gate connection 210c and the fourth gate connection 210d are formed integrally. In some embodiments, the second gate connection 210b, the third gate connection 210c, and the fourth gate connection 210d are further formed integrally.

In some embodiments, the gate isolation 107 is disposed between the first gate connection 210a and the second gate connection 210b. The top end of the gate isolation 107 contacts a bottom end of the second gate connection 210b and the bottom end of the gate isolation 107 contacts a top end of the first gate connection 210a. The first gate connection 210a and the second gate connection 210b are electrically isolated by the gate isolation 107. A top end of the gate isolation 107 is coplanar with a bottom end of the second gate connection 210b. Each of the first transistor 102a and the third transistor 102b is a P-MOSFET and each of the second transistor 104a and the fourth transistor 104b is a N-MOSFET. In some embodiments, each of the first transistor 102a and the third transistor 102b is a N-MOSFET and each of the second transistor 104a and the fourth transistor 104b is a P-MOSFET. In some embodiments, the first transistor 102a and the second transistor 104a are formed as a CFET and the third transistor 102b and the fourth transistor 104b are formed as a CFET. In some embodiments, the CFET has a first-type transistor stacked with a second-type transistor. Alternatively, the first-type transistor may have a channel (active) region in a first-type active-region semiconductor structure, and the second-type transistor may have a channel region in a second-type active-region semiconductor structure.

In some embodiments, the second transistor 104a, the third transistor 102b, and the fourth transistor 104b are configured to receive a control signal through the second gate connection 210b, the third gate connection 210c, and the fourth gate connection 210d. In some embodiments, the first transistor 102a is configured to receive another control signal through the first gate connection 210a. In some embodiments, a plurality of first conductive lines 112a is disposed in a first metal layer above the second transistor 104a. One of the plurality of first conductive lines 112a is electrically connected to the second gate connection 210b through a conductive via 126a. In some embodiments, the first transistor 102a is constructed in such a way that a P-type transistor includes an input from a voltage source or VDD. The second transistor 104a includes an N-type transistor that includes input from VSS or ground. In some embodiments, the semiconductor structure 1 includes a source/drain connection 132a and a source/drain connection 132b. In some embodiments, the semiconductor structure 1 includes the gate isolation 107, the conductive via 126a, the plurality of the first conductive lines 112a, the conductive via 124a, and the plurality of second conductive lines 109a.

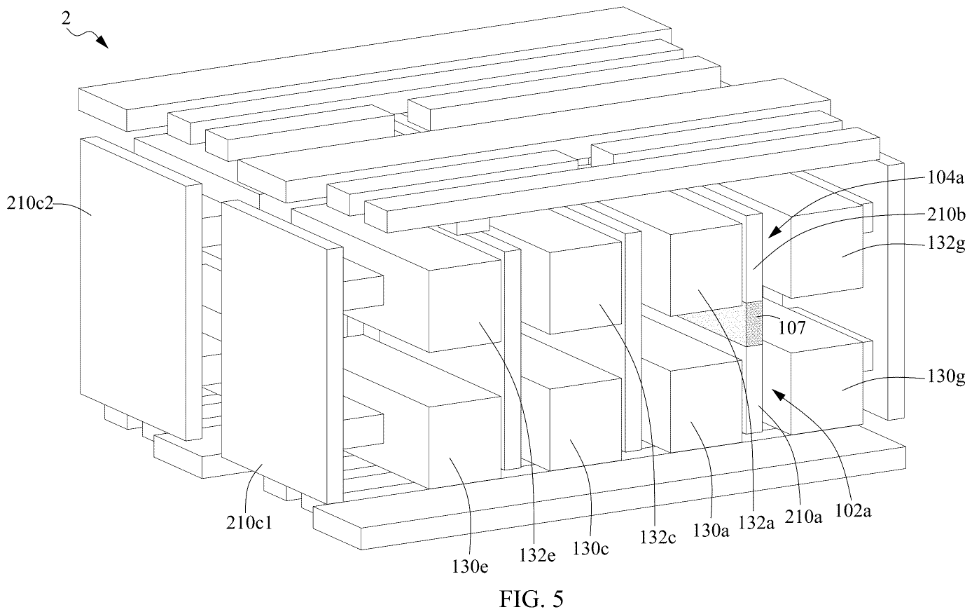

FIG. 5 is a three-dimensional view of the semiconductor structure 2 in accordance with some embodiments of the present disclosure. The semiconductor structure 2 includes a first transistor 102a, a second transistor 104a, a third transistor 102b, and a fourth transistor 104b. The second transistor 104a is disposed above the first transistor 102a. The fourth transistor 104b is disposed above the third transistor 102b. One cell includes the first transistor 102a and the second transistor 104a. Another cell includes the third transistor 102b and the fourth transistor 104b.

In some embodiments, the first transistor 102a is of a first conductivity type and comprises a first active region structure 106a. The second transistor 104a is of a second conductivity type different from the first conductivity type and comprises a second active region structure 108a. In some embodiments, the third transistor 102b is of the first conductivity type and comprises a third active region structure 106b. The fourth transistor 104b is of the second conductivity type and comprises a fourth active region structure 108b. The gate structure 210 includes a first gate connection 210a contacting the first active region structure 106a, a second gate connection 210b contacting the second active region structure 108a, a third gate connection 210c contacting the third active region structure 106b, and a fourth gate connection 210d contacting the fourth active region structure 108b. The third gate connection 210c and the fourth gate connection 210d are formed integrally. In some embodiments, the second gate connection 210b, the third gate connection 210c, and the fourth gate connection 210d are further formed integrally.

In some embodiments, the gate isolation 107 is disposed between the first gate connection 210a and the second gate connection 210b. The top end of the gate isolation 107 contacts a bottom end of the second gate connection 210b and the bottom end of the gate isolation 107 contacts a top end of the first gate connection 210a. The first gate connection 210a and the second gate connection 210b are electrically isolated by the gate isolation 107. A side surface of the first gate connection 210a is coplanar with a side surface of the gate isolation 107. A side surface of the second gate connection 210b is coplanar with a side surface of the gate isolation 107.

A top end of the gate isolation 107 is coplanar with a bottom end of the second gate connection 210b. Each of the first transistor 102a and the third transistor 102b is a P-MOSFET and each of the second transistor 104a and the fourth transistor 104b is a N-MOSFET. In some embodiments, each of the first transistor 102a and the third transistor 102b is a N-MOSFET and each of the second transistor 104a and the fourth transistor 104b is a P-MOSFET. In some embodiments, the first transistor 102a and the second transistor 104a are formed as a CFET and the third transistor 102b and the fourth transistor 104b are formed as a CFET. In some embodiments, the CFET has a first-type transistor stacked with a second-type transistor.

In some embodiments, the second transistor 104a, the third transistor 102b, and the fourth transistor 104b are configured to receive a control signal through the second gate connection 210b, the third gate connection 210c, and the fourth gate connection 210d. In some embodiments, the first transistor 102a is configured to receive another control signal through the first gate connection 210a. In some embodiments, a plurality of first conductive lines 112a is disposed in a first metal layer above the second transistor 104a.

In some embodiments, the semiconductor structure 2 includes a source/drain connection 132a and a source/drain connection 132b. In some embodiments, the semiconductor structure 2 includes the gate isolation 107, the conductive via 126a, the plurality of the first conductive lines 112a, the conductive via 124a, and the plurality of second conductive lines 109a. In some embodiments, the semiconductor structure 2 includes eight source/drain connections. In some embodiments, the semiconductor structure 2 includes two cut poly structures 210c1 and 210c2. In some embodiments, the material of the cut poly structures 210c1 and 210c2 includes dielectric materials or electrical isolation materials. In some embodiments, the cut poly structures include dummy poly structures 210c1 and 210c2 without transmitted electrical signals.

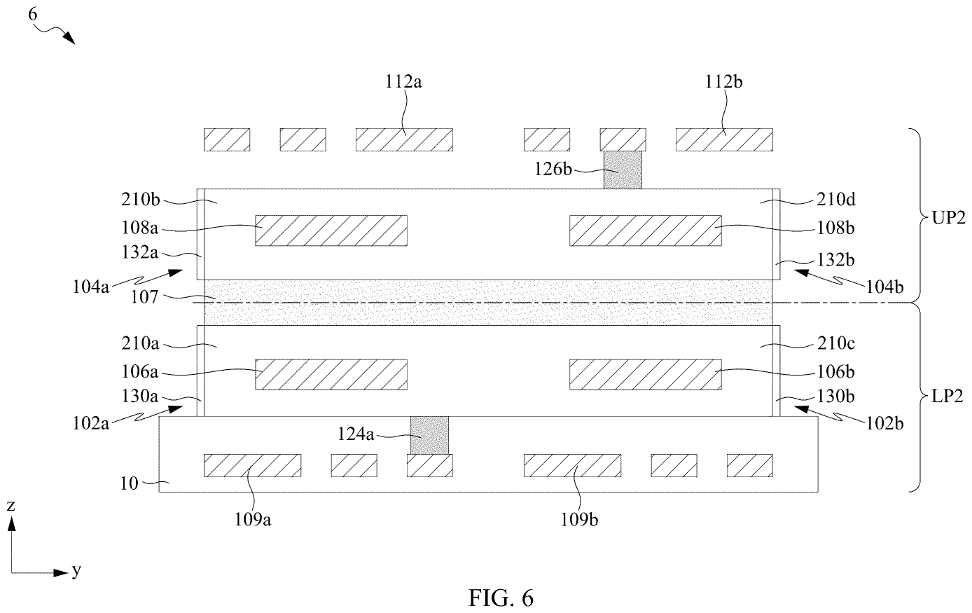

FIG. 6 is a cross-section of a semiconductor structure 6 in accordance with some embodiments of the present disclosure. The semiconductor structure 6 includes a semiconductor substrate 10, a first transistor 102a, a second transistor 104a, a third transistor 102b, and a fourth transistor 104b. The semiconductor structure 6 is similar to the semiconductor structure 1. The second transistor 104a is disposed above the first transistor 102a. The fourth transistor 104b is disposed above the third transistor 102b. One cell includes the first transistor 102a and the second transistor 104a. Another cell includes the third transistor 102b and the fourth transistor 104b. In some embodiments, the second gate connection 210b and the fourth gate connection 210d are formed integrally. In some embodiments, the first gate connection 210a and the third gate connection 210c are formed integrally. In some embodiments, the first gate connection 210a and the second gate connection 210b are electrically isolated by the gate isolation 107. The third gate connection 210c and the fourth gate connection 210d are electrically isolated by the gate isolation 107. In such embodiments, the gate isolation 107 continuously extends between the first gate connection 210a and the second gate connection 210b and between third gate connection 210c and the fourth gate connection 210d.

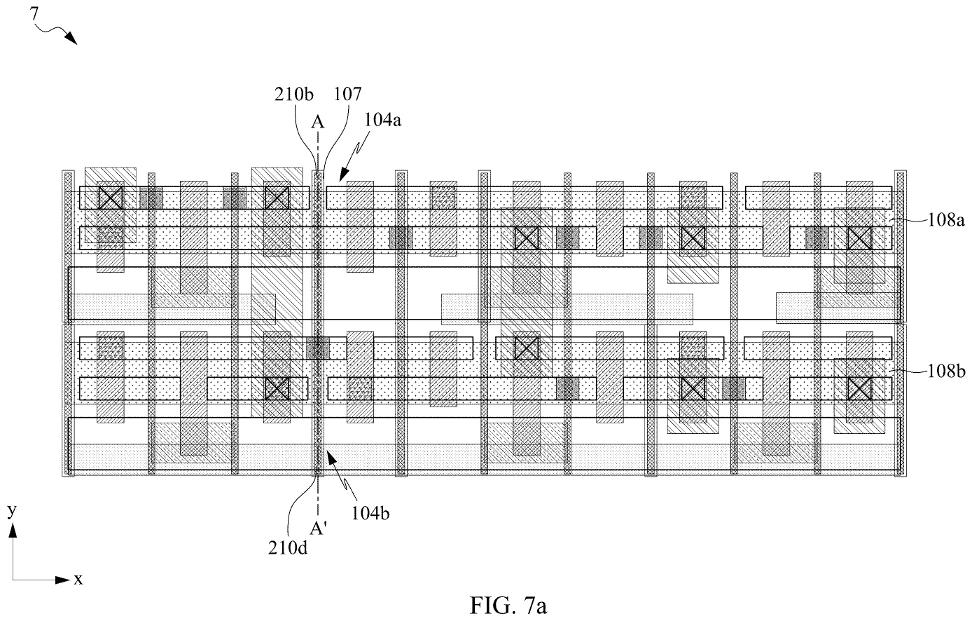

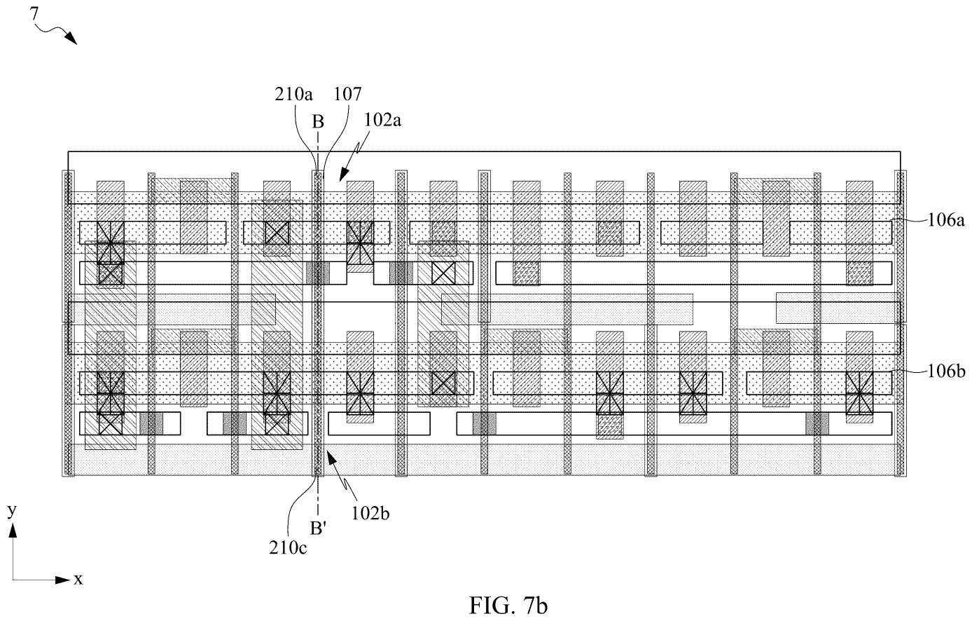

FIG. 7a is a schematic layout diagram of an upper portion of a semiconductor structure 7 in accordance with some embodiments of the present disclosure. The upper portion UP2 of the cross-section of the semiconductor structure 6 is obtained along line A-A′ of the upper portion of the semiconductor structure 7. The upper portion of the semiconductor structure 7 includes the second transistor 104a, the fourth transistor 104b, the second active region structure 108a, the fourth active region structure 108b, the second gate connection 210b, and the fourth gate connection 210d. In some embodiments, the upper portion of the semiconductor structure 7 includes a source/drain connection 132a and a source/drain connection 132b. In some embodiments, the upper portion of the semiconductor structure 7 includes the gate isolation 107, the conductive via 126a, and the plurality of the first conductive lines 112a. In some embodiments, the semiconductor structure 7 includes eight source/drain connections 132a-132h.

FIG. 7b is a schematic layout diagram of a lower portion of the semiconductor structure 7 in accordance with some embodiments of the present disclosure. The lower portion LP2 of the cross-section of the semiconductor structure 6 is obtained along line B-B′ of the lower portion of the semiconductor structure 7. The semiconductor structure 7 includes a first transistor 102a and a third transistor 102b. The lower portion of the semiconductor structure 7 includes the first transistor 102a, the third transistor 102b, the first active region structure 106a, the third active region structure 106b, the first gate connection 210a, and the second gate connection 210c. In some embodiments, the lower portion of the semiconductor structure 7 includes a source/drain connection 130a and a source/drain connection 130b. In some embodiments, the lower portion of the semiconductor structure 7 includes the gate isolation 107, a conductive via 124a, and the plurality of second conductive lines 109a. In some embodiments, the semiconductor structure 7b includes eight source/drain connections 130a-130h.

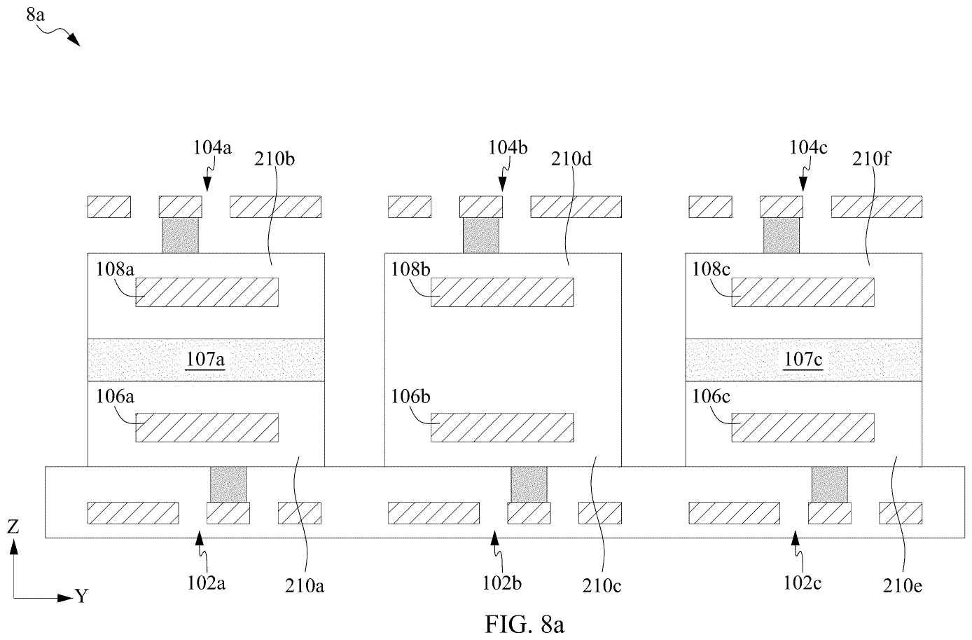

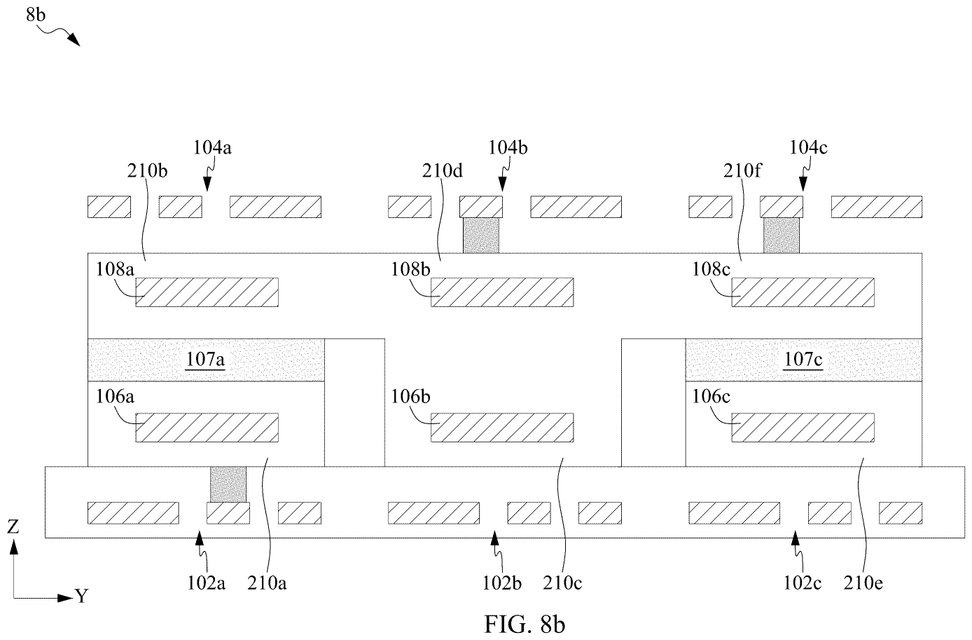

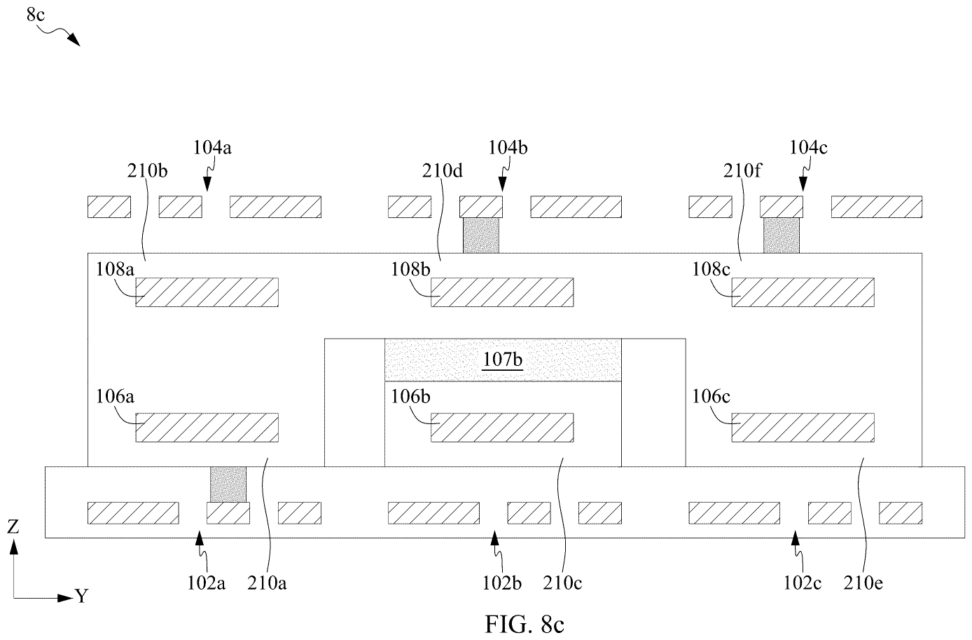

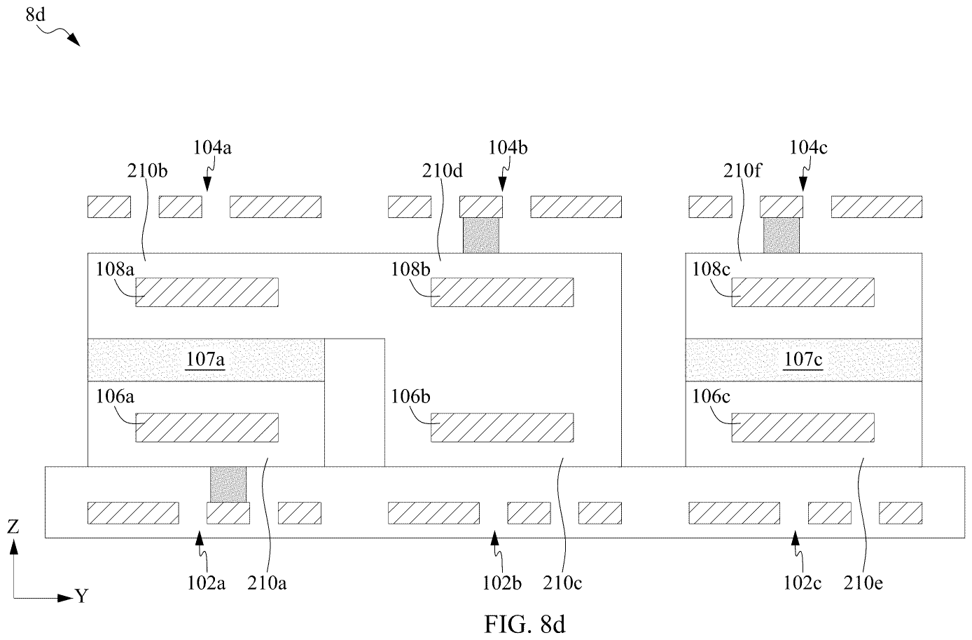

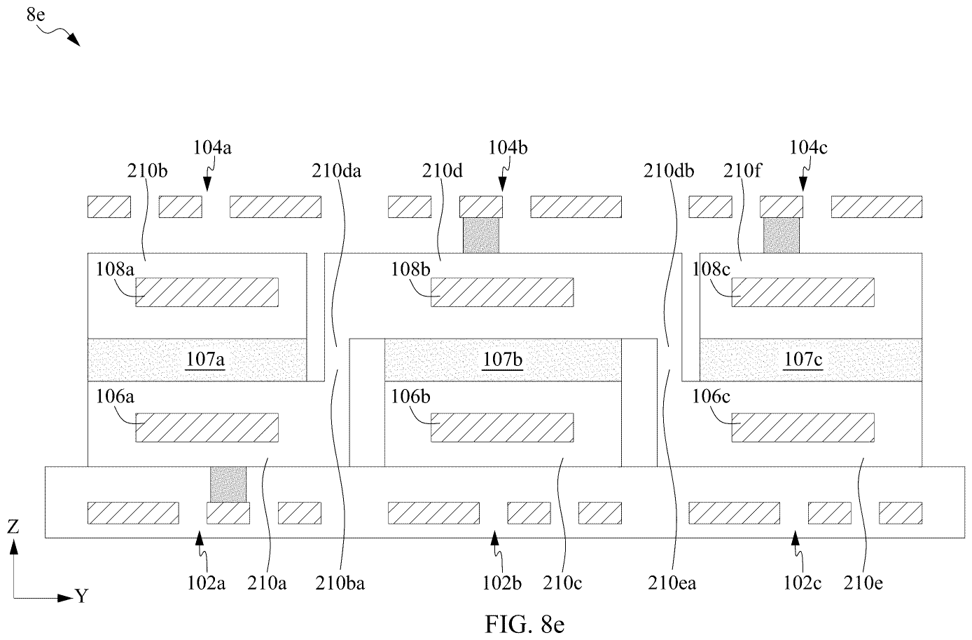

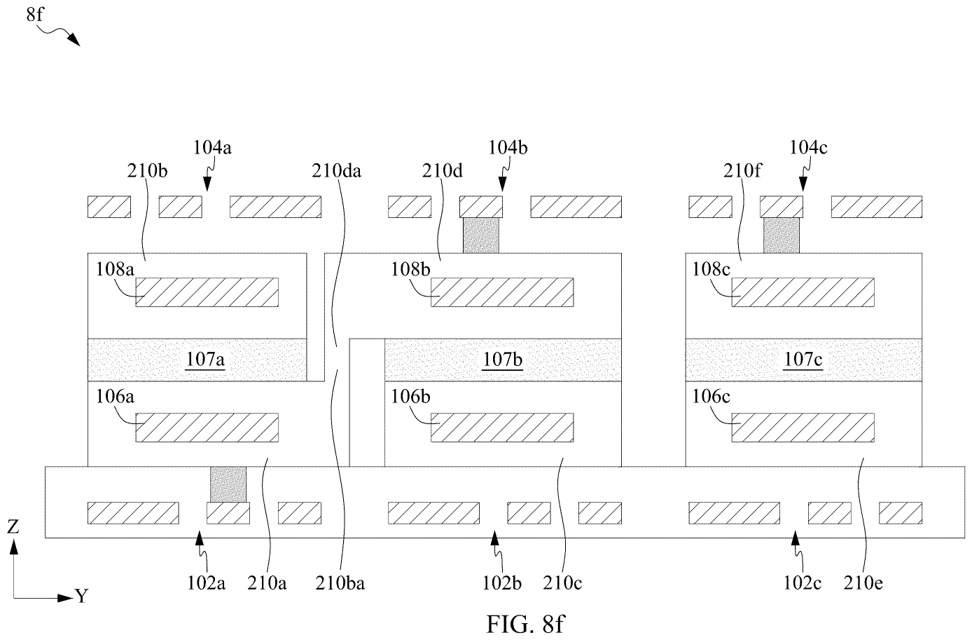

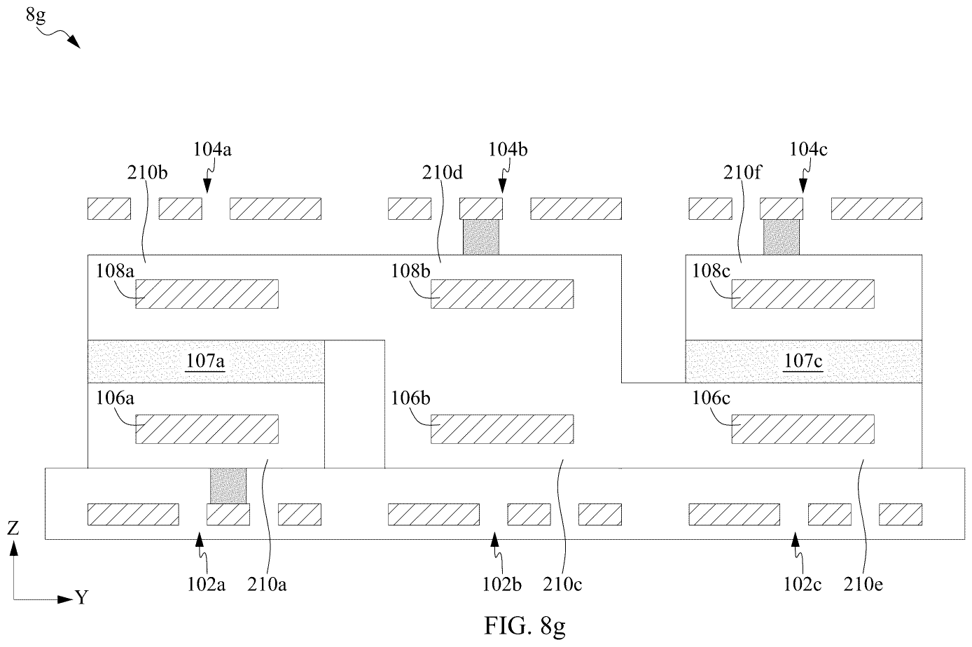

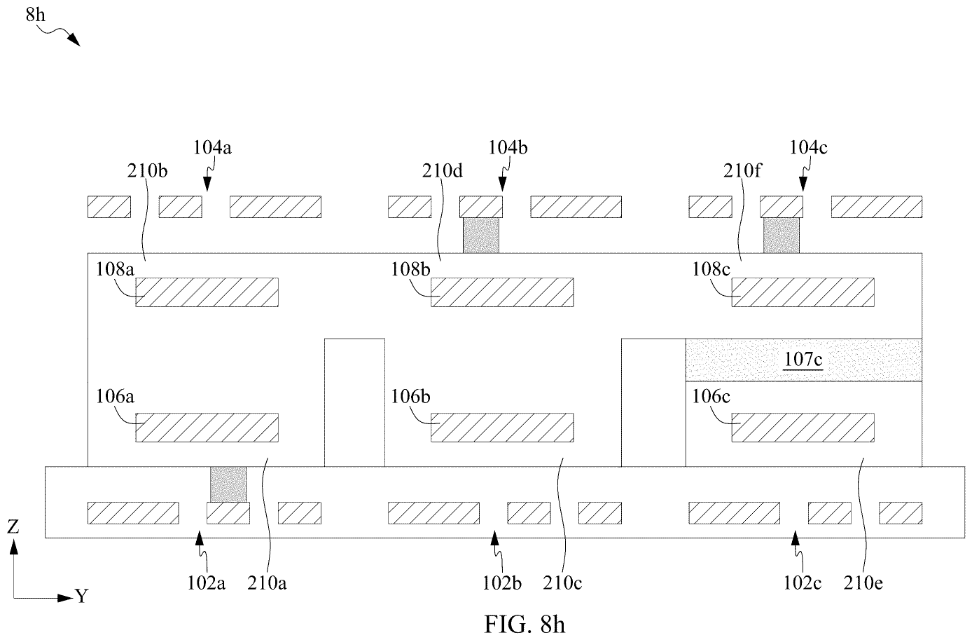

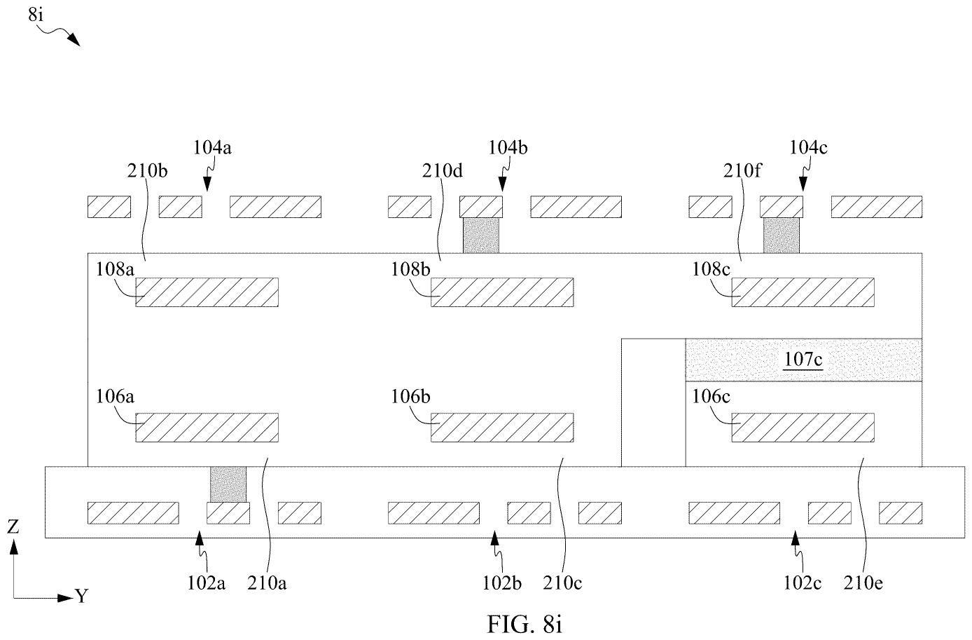

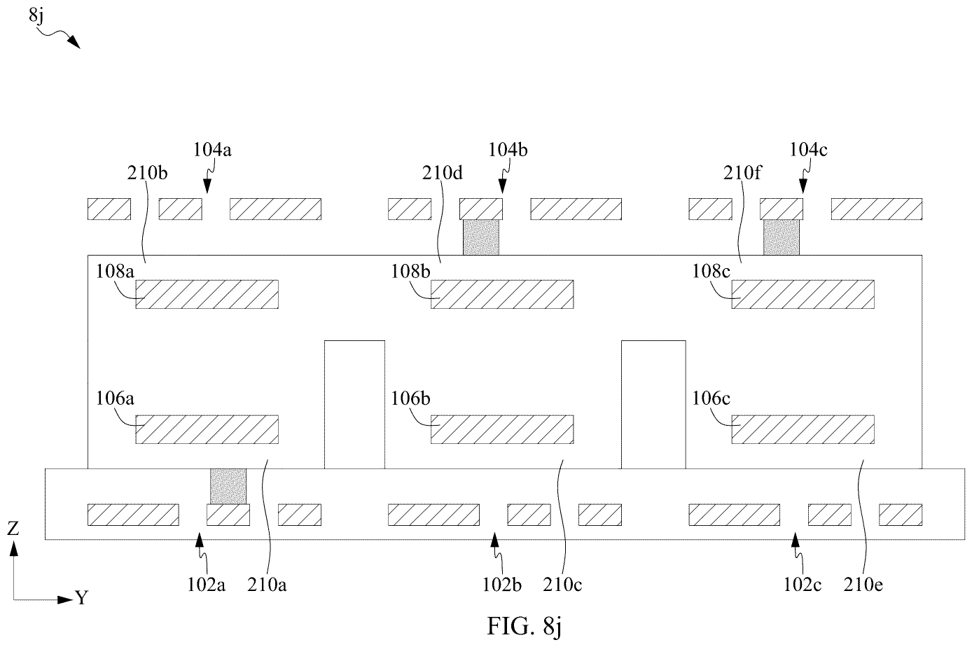

FIG. 8a is a cross-section of a semiconductor structure 8a in accordance with some embodiments of the present disclosure. The semiconductor structure 8a (also referred to herein as “three cells”) includes a first transistor 102a, a second transistor 104a, a third transistor 102b, a fourth transistor 104b, a fifth transistor 102c, and a sixth transistor 104c. The second transistor 104a is disposed above the first transistor 102a. The fourth transistor 104b is disposed above the third transistor 102b. The sixth transistor 104c is disposed above the fifth transistor 102c. One cell includes the first transistor 102a and the second transistor 104a. One cell includes the third transistor 102b and the fourth transistor 104b. Another cell includes the fifth transistor 102c and the sixth transistor 104c. The fifth transistor 102c is of the first conductivity type and comprises a fifth active region structure 106c. The sixth transistor 104c comprises the second conductivity type. The sixth transistor 104c comprises a sixth active region structure 108c. The gate structure comprises the first gate connection 210a contacting the first active region structure 106a, the second gate connection 210b contacting the second active region structure 108a, the third gate connection 210c contacting the third active region structure 106b, the fourth gate connection 210d contacting the fourth active region structure 108b, a fifth gate connection 210e contacting the fifth active region structure 106c, and a sixth gate connection 210f contacting the sixth active region structure 108c. A gate isolation 107a is disposed between the first gate connection 210a and the second gate connection 210b. A gate isolation 107c is disposed between the fifth gate connection 210e and the sixth gate connection 210f. The third gate connection 210c and the fourth gate connection 210d are formed integrally.

FIG. 8b is a cross-section of a semiconductor structure 8b in accordance with some embodiments of the present disclosure. The semiconductor structure 8b includes a first transistor 102a, a second transistor 104a, a third transistor 102b, a fourth transistor 104b, a fifth transistor 102c, and a sixth transistor 104c. The semiconductor structure 8b is similar to the semiconductor structure 8a. The gate structure comprises the first gate connection 210a contacting the first active region structure 106a, the second gate connection 210b contacting the second active region structure 108a, the third gate connection 210c contacting the third active region structure 106b, the fourth gate connection 210d contacting the fourth active region structure 108b, a fifth gate connection 210e contacting the fifth active region structure 106c, and a sixth gate connection 210f contacting the sixth active region structure 108c. A gate isolation 107c is disposed between the fifth gate connection 210e and the sixth gate connection 210f. The top end of the gate isolation 107a is coplanar with the top end of the gate isolation 107c. The bottom end of the gate isolation 107a is coplanar with the bottom end of the gate isolation 107c. The second gate connection 210b, the third gate connection 210c, the fourth gate connection 210d, and the sixth gate connection 210f are formed integrally.

FIG. 8c is a cross-section of a semiconductor structure 8c in accordance with some embodiments of the present disclosure. The semiconductor structure 8c includes a first transistor 102a, a second transistor 104a, a third transistor 102b, a fourth transistor 104b, a fifth transistor 102c, and a sixth transistor 104c. The semiconductor structure 8c is similar to the semiconductor structure 8a. A gate isolation 107b is disposed between the third gate connection 210c and the fourth gate connection 210d. The first gate connection 210a, the second gate connection 210b, the fourth gate connection 210d, the fifth gate connection 210e, and the sixth gate connection 210f are formed integrally.

FIG. 8d is a cross-section of a semiconductor structure 8d in accordance with some embodiments of the present disclosure. The semiconductor structure 8d includes a first transistor 102a, a second transistor 104a, a third transistor 102b, a fourth transistor 104b, a fifth transistor 102c, and a sixth transistor 104c. The semiconductor structure 8d is similar to the semiconductor structure 8a. A gate isolation 107a is disposed between the first gate connection 210a and the second gate connection 210b. A gate isolation 107c is disposed between the fifth transistor 102c and the sixth transistor 104c. The second gate connection 210b, the third gate connection 210c, and the fourth gate connection 210d are formed integrally.

FIG. 8e is a cross-section of a semiconductor structure 8d in accordance with some embodiments of the present disclosure. The semiconductor structure 8d includes a first transistor 102a, a second transistor 104a, a third transistor 102b, a fourth transistor 104b, a fifth transistor 102c, and a sixth transistor 104c. The semiconductor structure 8e is similar to the semiconductor structure 8a. A gate isolation 107a is disposed between the first gate connection 210a and the second gate connection 210b. A gate isolation 107b is disposed between the third gate connection 210c and the fourth gate connection 210d. A gate isolation 107c is disposed between the fifth transistor 102c and the sixth transistor 104c. The second gate connection 210b, the fourth gate connection 210d, and the fifth gate connection 210e are formed integrally. The fifth gate connection 210e further comprises a top protrusion 210ea protruded from a top end of the fifth gate connection 210e. The fourth gate connection 210d further comprises a bottom protrusion 210db protruded from a bottom end of the fourth gate connection 210d. The top protrusion 210ea contacts the bottom protrusion 210db. The second gate connection 210b further comprises a top protrusion 210ba protruded from a top end of the second gate connection 210b. The fourth gate connection 210d further comprises a bottom protrusion 210da protruded from a bottom end of the fourth gate connection 210d. The top protrusion 210ba contacts the bottom protrusion 210da.

FIG. 8f is a cross-section of a semiconductor structure 8f in accordance with some embodiments of the present disclosure. The semiconductor structure 8f includes a first transistor 102a, a second transistor 104a, a third transistor 102b, a fourth transistor 104b, a fifth transistor 102c, and a sixth transistor 104c. The semiconductor structure 8f is similar to the semiconductor structure 8a. A gate isolation 107a is disposed between the first gate connection 210a and the second gate connection 210b. A gate isolation 107b is disposed between the third gate connection 210c and the fourth gate connection 210d. A gate isolation 107c is disposed between the fifth transistor 102c and the sixth transistor 104c. The second gate connection 210b and the fourth gate connection 210d are formed integrally. The second gate connection 210b further comprises a top protrusion 210ba protruded from a top end of the second gate connection 210b. The fourth gate connection 210d further comprises a bottom protrusion 210da protruded from a bottom end of the fourth gate connection 210d. The top protrusion 210ba contacts the bottom protrusion 210da. The top protrusion 210ba contacting the bottom protrusion 210da can increase the routing tracks in CFET structures and can reduce the length of the cell pitches. The design of the structures causes the routing of the CFET structures more flexible. In some embodiments, the design can reduce the coupling of the metal layer due to the clear metal routings of CFET structures. The design of the structures increases flexibility for the circuit design. The first transistor 102a and the second transistor 104a which comprise different gates are controlled by different signals separately due to the gate isolation 107a. In some embodiments, any of the gate connections 210a-210f can be replaced with dielectric materials or electrical isolation materials.

FIG. 8g is a cross-section of a semiconductor structure 8g in accordance with some embodiments of the present disclosure. The semiconductor structure 8g includes a first transistor 102a, a second transistor 104a, a third transistor 102b, a fourth transistor 104b, a fifth transistor 102c, and a sixth transistor 104c. The second gate connection 210b, the third gate connection 210c, the fourth gate connection 210d, and the fifth gate connection 210e are formed integrally.

FIG. 8h is a cross-section of a semiconductor structure 8h in accordance with some embodiments of the present disclosure. The semiconductor structure 8h includes a first transistor 102a, a second transistor 104a, a third transistor 102b, a fourth transistor 104b, a fifth transistor 102c, and a sixth transistor 104c. The first gate connection 210a, the second gate connection 210b, the third gate connection 210c, the fourth gate connection 210d, and the sixth gate connection 210f are formed integrally.

FIG. 8i is a cross-section of a semiconductor structure 8i in accordance with some embodiments of the present disclosure. The semiconductor structure 8i includes a first transistor 102a, a second transistor 104a, a third transistor 102b, a fourth transistor 104b, a fifth transistor 102c, and a sixth transistor 104c. The first gate connection 210a, the second gate connection 210b, the third gate connection 210c, the fourth gate connection 210d, and the sixth gate connection 210f are formed integrally.

FIG. 8j is a cross-section of a semiconductor structure 8j in accordance with some embodiments of the present disclosure. The semiconductor structure 8j includes a first transistor 102a, a second transistor 104a, a third transistor 102b, a fourth transistor 104b, a fifth transistor 102c, and a sixth transistor 104c. The first gate connection 210a, the second gate connection 210b, the third gate connection 210c, the fourth gate connection 210d, the fifth gate connection 210e, and the sixth gate connection 210f are formed integrally.

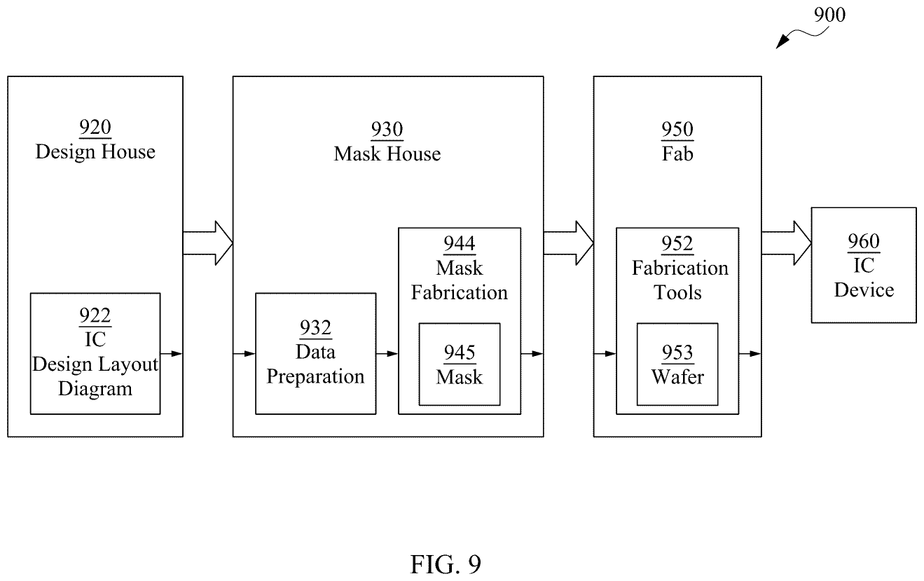

FIG. 9 is a block diagram of an integrated circuit (IC) manufacturing system 900, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 900.

In some embodiments, in FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. Additionally or alternatively, the entities in system 900 are connected by a communications network. In some embodiments, the communications network is a single network. In some embodiments, the communications network is a variety of different networks, such as an intranet and the Internet. Additionally or alternatively, the communications network includes wired and/or wireless communication channels. In some embodiments, each entity interacts with one or more of the other entities and provides services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

In some embodiments, design house (or design team) 920 generates an IC design layout diagram 922. Additionally or alternatively, IC design layout diagram 922 includes various geometrical patterns designed for an IC device 960. In some embodiments, the geometrical patterns correspond to patterns of metal, oxide, or semiconductor layers that make up the various components of IC device 960 to be fabricated. Additionally or alternatively, the various layers combine to form various IC features. For example, a portion of IC design layout diagram 922 includes various IC features, such as an active region, gate terminal, source terminal and drain terminal, metal lines or vias of an interlayer interconnection, and openings for bonding pads, to be formed in a semiconductor substrate (such as a silicon wafer) and various material layers on the semiconductor substrate. In some embodiments, design house 920 implements a proper design procedure to form IC design layout diagram 922. Additionally or alternatively, the design procedure includes one or more of logic design, physical design, or place and route. In some embodiments, IC design layout diagram 922 is presented in one or more data files having information of the geometrical patterns. For example, IC design layout diagram 922 is expressed in a GDSII file format or DFII file format.

In some embodiments, mask house 930 includes mask data preparation 932 and mask fabrication 944. Additionally or alternatively, mask house 930 uses IC design layout diagram 922 to manufacture one or more masks 945 to be used for fabricating the various layers of IC device 960 according to IC design layout diagram 922. In some embodiments, mask house 930 performs mask data preparation 932, where IC design layout diagram 922 is translated into a representative data file (“RDF”). Additionally or alternatively, mask data preparation 932 provides the RDF to mask fabrication 944. In some embodiments, mask fabrication 944 includes a mask writer. Additionally or alternatively, a mask writer converts the RDF to an image on a substrate, such as a mask (reticle) 945 or a semiconductor wafer 953. In some embodiments, the design layout diagram 922 is manipulated by mask data preparation 932 to comply with particular characteristics of the mask writer and/or requirements of IC fab 950. Additionally or alternatively, in FIG. 9, mask data preparation 932 and mask fabrication 944 are illustrated as separate elements. In some embodiments, mask data preparation 932 and mask fabrication 944 are collectively referred to as mask data preparation.

In some embodiments, mask data preparation 932 includes optical proximity correction (OPC) which uses lithography enhancement techniques to compensate for image errors, such as those that arise from diffraction, interference, other process effects and the like. Additionally or alternatively, OPC adjusts IC design layout diagram 922. In some embodiments, mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 932 includes a mask rule checker (MRC) that checks the IC design layout diagram 922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 922 to compensate for limitations during mask fabrication 944, which undoes part of the modifications performed by OPC in order to meet mask creation rules.

In some embodiments, mask data preparation 932 includes lithography process checking (LPC) that simulates processing that will be implemented by IC fab 950 to fabricate IC device 960. Additionally or alternatively, LPC simulates this processing based on IC design layout diagram 922 to create a simulated manufactured device, such as IC device 960. In some embodiments, the processing parameters in LPC simulation include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are repeated to further refine IC design layout diagram 922.

In some embodiments, the foregoing description of mask data preparation 932 has been simplified for the purposes of clarity. In some embodiments, mask data preparation 932 includes additional features such as a logic operation (LOP) to modify the IC design layout diagram 922 according to manufacturing rules. Additionally, the processes applied to IC design layout diagram 922 during mask data preparation 932 are executed in a variety of different orders.

In some embodiments, after mask data preparation 932 and during mask fabrication 944, a mask 945 or a group of masks 945 are fabricated based on the modified IC design layout diagram 922. In some embodiments, mask fabrication 944 includes performing one or more lithographic exposures based on IC design layout diagram 922. In some embodiments, an electron-beam (e-beam) or a mechanism of multiple e-beams is used to form a pattern on a mask (photomask or reticle) 945 based on the modified IC design layout diagram 922. Additionally or alternatively, mask 945 is formed in various technologies. In some embodiments, mask 945 is formed using binary technology. In some embodiments, a mask pattern includes opaque regions and transparent regions. Additionally or alternatively, a radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 945 includes a transparent substrate (e.g., fused quartz) and an opaque material (e.g., chromium) coated in the opaque regions of the binary mask. In another example, mask 945 is formed using a phase shift technology. In a phase shift mask (PSM) version of mask 945, various features in the pattern formed on the phase shift mask are configured to have proper phase difference to enhance the resolution and imaging quality. In various examples, the phase shift mask is attenuated PSM or alternating PSM. Additionally or alternatively, the masks generated by mask fabrication 944 are used in a variety of processes. For example, such masks can be used in an ion implantation process to form various doped regions in semiconductor wafer 953, in an etching process to form various etching regions in semiconductor wafer 953, and/or in other suitable processes.

In some embodiments, IC fab 950 is an IC fabrication business that includes one or more manufacturing facilities for the fabrication of a variety of different IC products. In some embodiments, IC fab 950 is a semiconductor foundry. For example, there can be a manufacturing facility for the front end fabrication of a plurality of IC products (front-end-of-line (FEOL) fabrication), while a second manufacturing facility provides the back end fabrication for the interconnection and packaging of the IC products (back-end-of-line (BEOL) fabrication), and a third manufacturing facility provides other services for the foundry business.

In some embodiments, IC fab 950 includes fabrication tools 952 configured to execute various manufacturing operations on semiconductor wafer 953 such that IC device 960 is fabricated in accordance with the masks, e.g. mask 945. In various embodiments, fabrication tools 952 include one or more of a wafer stepper, an ion implanter, a photoresist coater, a process chamber, e.g. a CVD chamber or LPCVD furnace, a CMP system, a plasma etch system, a wafer cleaning system, or other manufacturing equipment capable of performing one or more suitable manufacturing processes as discussed herein.

In some embodiments, IC fab 950 uses mask(s) 945 fabricated by mask house 930 to fabricate IC device 960. Additionally or alternatively, IC fab 950 at least indirectly uses IC design layout diagram 922 to fabricate IC device 960. In some embodiments, semiconductor wafer 953 is fabricated by IC fab 950 using mask(s) 945 to form IC device 960. In some embodiments, the IC fabrication includes performing one or more lithographic exposures based at least indirectly on IC design layout diagram 922. In some embodiments, semiconductor wafer 953 includes a silicon substrate or other proper substrate having material layers formed thereon. Additionally or alternatively, semiconductor wafer 953 further includes one or more of various doped regions, dielectric features, multilevel interconnects, and the like (formed in subsequent manufacturing steps).

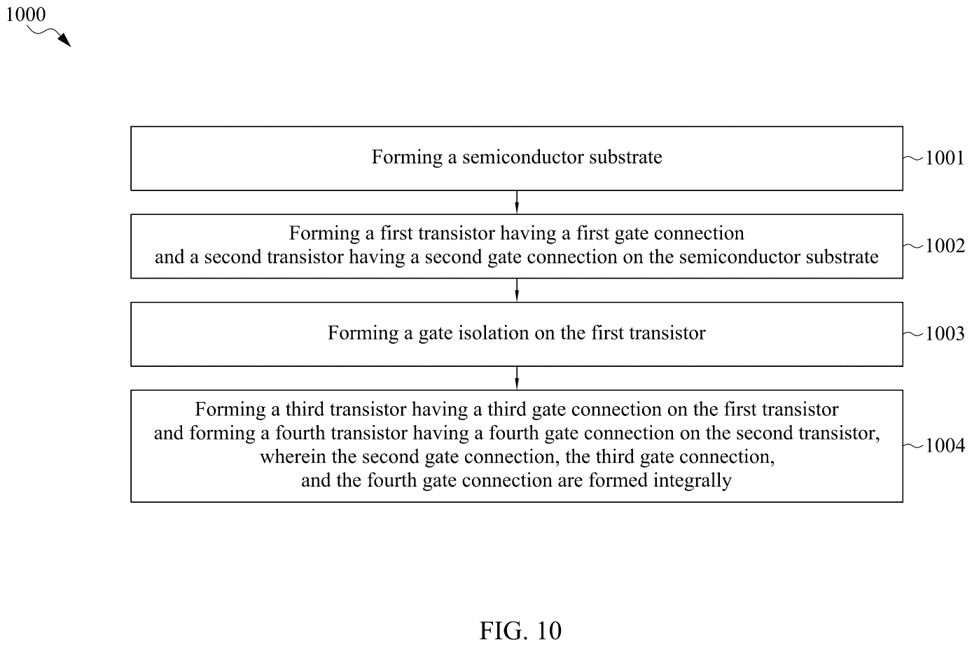

FIG. 10 is a flowchart of an embodiment of a method 1000 of manufacturing a semiconductor structure 1 in accordance with some embodiments of the present disclosure. In some embodiments, the method may include various operations for manufacturing the semiconductor structure 1. The method 1000 includes forming a semiconductor substrate 10 (operation 1001). The method 1000 includes forming a first transistor 102a having a first gate connection 210a and a second transistor 102b having a second gate connection 210c on the semiconductor substrate 10 (operation 1002). In some embodiments, the first transistor 102a and the second transistor 102b respectively are of a first conductivity type. The method 1000 includes forming a gate isolation 107 on the first transistor 102a (operation 1003). The method 1000 includes forming a third transistor 104a having a third gate connection 210b on the first transistor 102a and forming a fourth transistor 104b having a fourth gate connection 210d on the second transistor 102b (operation 1004). In some embodiments, the second transistor 102b and the fourth transistor 104b respectively are of a second conductivity type. The first gate connection 210a and the third gate connection 210b are electrically isolated by the gate isolation 107. The second gate connection 210c, the third gate connection 210b, and the fourth gate connection 210d are formed integrally. Each of the first transistor 102a and the second transistor 102b is a P-MOSFET and each of the third transistor 104a and the fourth transistor 104b is a N-MOSFET. It should be noted that the method of manufacturing semiconductor structures in accordance with some embodiments of the present disclosure includes, but is not limited to, the mentioned processes.

Some exemplary embodiments of semiconductor structures include (a) a gate isolation 107 disposed between the first gate connection 210a and the second gate connection 210b; (b) wherein the first gate connection 210a and the second gate connection 210b are electrically isolated by the gate isolation 107; and (c) wherein the second gate connection 210b, the third gate connection 210c and the fourth gate connection 210d are formed integrally. The design of the structures renders routing of the CFET structures more flexible. In some embodiments, the design can reduce the coupling of the metal layer due to the clear metal routings of CFET structures. The design of the structures increases flexibility of the circuit design.

According to some embodiments, a semiconductor structure includes a first transistor, a second transistor, a gate structure, and a gate isolation. The first transistor is of a first conductivity type and comprises a first active region structure. The second transistor is of a second conductivity type different from the first conductivity type and comprises a second active region structure. The second transistor is disposed above the first transistor. The gate structure comprises a first gate connection contacting the first active region structure and a second gate connection contacting the second active region structure. The gate isolation is disposed between the first gate connection and the second gate connection.

According to other embodiments, a semiconductor structure comprises a first transistor, a second transistor, a third transistor, a fourth transistor, a gate structure, and a first gate isolation. The first transistor is of a first conductivity type and comprises a first active region structure. The second transistor is of a second conductivity type different from the first conductivity type and comprises a second active region structure. The second transistor is disposed above the first transistor. The third transistor is of the first conductivity type and comprises a third active region structure. The fourth transistor is of the second conductivity type and comprises a fourth active region structure. The fourth transistor being disposed above the third transistor. The gate structure comprises a first gate connection contacting the first active region structure, a second gate connection contacting the second active region structure, a third gate connection contacting the third active region structure, and a fourth gate connection contacting the fourth active region structure. The first gate isolation is disposed between the first gate connection and the second gate connection and wherein each of the first transistor and the third transistor is a P-MOSFET and each of the second transistor and the fourth transistor is a N-MOSFET.

According to some embodiments, a method for manufacturing a semiconductor structure includes forming a semiconductor substrate, forming a first transistor having a first gate connection and a second transistor having a second gate connection on the semiconductor substrate, wherein the first transistor and the second transistor respectively are of a first conductivity type, forming a gate isolation on the first transistor, forming a third transistor having a third gate connection on the first transistor and forming a fourth transistor having a fourth gate connection on the second transistor, wherein the second transistor and the fourth transistor are respectively of a second conductivity type, wherein the second gate connection, the third gate connection, and the fourth gate connection are formed integrally, and wherein the first gate connection and the third gate connection are electrically isolated by the gate isolation.

The methods and features of the present disclosure have been sufficiently described in the examples and descriptions provided. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A semiconductor structure comprising:
a first transistor of a first conductivity type and comprising a first active region structure;
a second transistor of a second conductivity type different from the first conductivity type and comprising a second active region structure, the second transistor being disposed above the first transistor;
a gate structure comprising a first gate connection contacting the first active region structure and a second gate connection contacting the second active region structure; and
a gate isolation disposed between the first gate connection and the second gate connection.

2. The semiconductor structure of claim 1, wherein the first gate connection and the second gate connection are electrically isolated by the gate isolation.

3. The semiconductor structure of claim 1, wherein a lateral width of the first gate connection is substantially the same as a lateral width of the gate isolation.

4. The semiconductor structure of claim 1, further comprising:
a third transistor of the first conductivity type and comprising a third active region structure; and
a fourth transistor of the second conductivity type and comprising a fourth active region structure, the fourth transistor being disposed above the third transistor;
wherein the gate structure further comprises a third gate connection contacting the third active region structure and a fourth gate connection contacting the fourth active region structure, wherein the third gate connection and the fourth gate connection are formed integrally.

5. The semiconductor structure of claim 4, wherein the second gate connection, the third gate connection, and the fourth gate connection are further formed integrally.

6. The semiconductor structure of claim 5, wherein each of the first transistor and the third transistor is a P-channel metal-oxide semiconductor field-effect transistor (P-MOSFET) and each of the second transistor and the fourth transistor is a N-MOSFET.

7. The semiconductor structure of claim 4, wherein the second transistor, the third transistor, and the fourth transistor are configured to receive a control signal through the second gate connection, the third gate connection, and the fourth gate connection.

8. The semiconductor structure of claim 4, wherein the second gate connection of the second transistor contacts the fourth gate connection of the fourth transistor from a top view and wherein a width of the second gate connection is the same as a width of the fourth gate connection from the top view.

9. The semiconductor structure of claim 8, wherein the width of the second gate connection is the same as a width of the gate isolation from the top view.

10. The semiconductor structure of claim 1, further comprising a plurality of first conductive lines in a first metal layer above the second transistor, and wherein one of a plurality of first conductive lines is electrically connected to the second gate connection through a conductive via.

11. A semiconductor structure comprising:
a first transistor of a first conductivity type and comprising a first active region structure;
a second transistor of a second conductivity type different from the first conductivity type and comprising a second active region structure, the second transistor being disposed above the first transistor;
a third transistor of the first conductivity type and comprises a third active region structure;
a fourth transistor of the second conductivity type and comprises a fourth active region structure, the fourth transistor being disposed above the third transistor;
a gate structure comprising a first gate connection contacting the first active region structure, a second gate connection contacting the second active region structure, a third gate connection contacting the third active region structure, and a fourth gate connection contacting the fourth active region structure; and
a first gate isolation disposed between the first gate connection and the second gate connection and wherein each of the first transistor and the third transistor is a P-MOSFET and each of the second transistor and the fourth transistor is a N-MOSFET.

12. The semiconductor structure of claim 11, wherein the second gate connection, the third gate connection, and the fourth gate connection are formed integrally.

13. The semiconductor structure of claim 11, wherein the first gate connection and the second gate connection are electrically isolated by the first gate isolation.

14. The semiconductor structure of claim 11, further comprising:
a fifth transistor of the first conductivity type and comprising a fifth active region structure;
a sixth transistor disposed above the fifth transistor, wherein the sixth transistor comprises the second conductivity type, wherein the sixth transistor comprises a sixth active region structure, wherein the gate structure further comprises a fifth gate connection contacting the fifth active region structure and a sixth gate connection contacting the sixth active region structure; and
a second gate isolation disposed between the fifth gate connection and the sixth gate connection and wherein the second gate connection, the third gate connection, the fourth gate connection, and the sixth gate connection are formed integrally.

15. The semiconductor structure of claim 14, wherein a top end of the first gate isolation is coplanar with a bottom end of the second gate connection and wherein the top end of the first gate isolation is coplanar with a top end of the second gate isolation.

16. The semiconductor structure of claim 11, wherein the first gate connection further comprises a first top protrusion protruded from a top end of the first gate connection and the fourth gate connection further comprises a first bottom protrusion protruded from a bottom end of the fourth gate connection, wherein the first top protrusion contacts the first bottom protrusion.

17. The semiconductor structure of claim 16, further comprising:
a fifth transistor of the first conductivity type and comprising a fifth active region structure;
a sixth transistor disposed above the fifth transistor, wherein the sixth transistor comprises the second conductivity type, wherein the sixth transistor comprises a sixth active region structure,
wherein the gate structure further comprises a fifth gate connection contacting the fifth active region structure and a sixth gate connection contacting the sixth active region structure;
wherein the fifth gate connection further comprises a second top protrusion protruded from a top end of the fifth gate connection and the fourth gate connection further comprises a second bottom protrusion protruded from a bottom end of the fourth gate connection, wherein the second top protrusion contacts the second bottom protrusion.

18. A method for manufacturing a semiconductor structure comprising:
forming a semiconductor substrate;
forming a first transistor having a first gate connection and a second transistor having a second gate connection on the semiconductor substrate, wherein the first transistor and the second transistor respectively are of a first conductivity type;
forming a gate isolation on the first transistor;
forming a third transistor having a third gate connection on the first transistor and forming a fourth transistor having a fourth gate connection on the second transistor, wherein the second transistor and the fourth transistor respectively are of a second conductivity type, wherein the second gate connection, the third gate connection, and the fourth gate connection are formed integrally, and wherein the first gate connection and the third gate connection are electrically isolated by the gate isolation.

19. The method of claim 18, wherein a lateral width of the first gate connection is substantially the same as a lateral width of the gate isolation.

20. The method of claim 18, wherein each of the first transistor and the second transistor is a P-channel metal-oxide semiconductor field-effect transistor (P-MOSFET) and each of the third transistor and the fourth transistor is a N-MOSFET.
